(19) United States
(12) Patent Application Publication
(10) Pub. No.: US 2011/0024842 A1
(43) Pub. Date: Feb. 3, 2011

(54) PROCEDURE FOR THE USE OF NATURAL CELLULOSIC MATERIAL, SYNTHETIC MATERIAL OR MIXED NATURAL AND SYNTHETIC MATERIAL, SIMULTANEOUSLY AS PHYSICAL AND DIELECTRIC SUPPORT IN SELF-SUSTAINABLE FIELD EFFECT ELECTRONIC AND OPTOELECTRONIC DEVICES

(76) Inventors: Rodrigo Ferrão de Paiva Martins, Charneca de Caparica (PT); Elvira Maria Corrreia Fortunato, Charneca de Caparica (PT)

Correspondence Address: KENEALY VAIDYA LLP, 515 EAST BRADDOCK RD SUITE B, Alexandria, VA, 22314, US

(21) Appl. No.: 12/933,661

(22) PCT Filed: Mar. 20, 2009
(86) PCT No.: PCT/IB09/00565

§ 371 Date: Oct. 19, 2010

(30) Foreign Application Priority Data
Mar. 20, 2008 (PT) 103998

(51) Int. Cl. H01L 29/786; H01L 21/20

(52) U.S. Cl. 257/347; 438/478; 257/E21.09; 257/E29.273

(57) ABSTRACT

The present invention refers to the use and creation of natural cellulosic material, synthetic or mixed material and corresponding production process to be used simultaneously as physical and dielectric support in the creation of new field-effect electronic or optoelectronic devices, designated C-MOS structured electronic devices, designated interstrate, wherein its functionality depends on the capacity per unit area of the paper depending on how the fibers thereof are distributed, the fibers being coated by an active ionic or covalent semiconductor and allowing the production of flexible self-sustainable devices, disposable devices, based on the new integrated interstrate concept, of monolithic or hybrid types.

### TECHNICAL FIELD OF THE INVENTION

The present invention relates generally to the use of material composed of cellulose-based natural, synthetic or mixed fibers, united both physically and chemically by hydrogen bridges, usually designated paper, in its various forms and constitutions, such as: thermal sensitive paper or alkaline paper or craft paper or bible paper or cardboard paper or coated paper or paper towels or toilet paper or, newspaper, photo paper or copier paper or offset paper or architect paper, or vegetable paper or cellophane paper from now on simply referred to as paper functioning simultaneously as physical support of electronic or optoelectronics devices and constituent element of these devices as a dielectric.

The present invention is based on the use of paper of different thicknesses (between 1 micrometers and 4000 micrometers) and surface finish as dielectric material and physical support in active electronic devices such as field-effect transistors in which one side of the paper is deposited with a metal electrode for the injection of electrical charges and at the other side is deposited with a semiconductor material, either organic or inorganic, ionic or covalent, to act as a channel of the device (1) in diode-type structures. In addition to the active semiconductor, this face of the semiconductor may contain the other two typical regions for the manufacture and creation of a field-effect transistor which are the drain and source regions (5).

In the present invention the two sides of the paper are used as a support for additional components for the manufacture of an electronic or optoelectronic device carrying out through this the integration of components, namely the control process of charges being injected into a semiconductor, serving simultaneously as a physic support of the device or devices to be integrated in order to form a consistent system that allows the transformation of the paper into an electronically-activated dynamic element. For the processing of all materials to be deposited onto the paper so that it can be used simultaneously as material dielectric and support (from now on designated electronic devices of C-MOS interstrate structure), it is necessary that the manufacturing technologies of these films occur at low temperatures, particularly, at temperatures below 150 degrees Celsius or that when annealed this temperature is not exceeded.

The C-MOS interstrate structures, which means that the dielectric is simultaneously a substrate and dielectric, can be used in electronics and optoelectronics, particularly in the production of field-effect complementary devices, logic gates, ring oscillators and in thin film transistors, without the need of any substrate for its physical support and wherein a layer of protection or final encapsulation such as magnesium fluoride can be used, being then applied in the electronic industry, in the semiconductor industry, in the industry of flat screen displays and similar industries, in the logic circuit industry, in the instrumentation and sensors industry, in the medical and biotechnological industry, in the optoelectronic and solar cells industry, in the micro and nano-electronics industry.

The present invention wherein paper is the dielectric being simultaneously the support of singular and integrated devices, the active semiconductors may be organic (for example, N,N′-diphenyl-N,N-bis[3-methylphenyl]-1,1′ biphenyl-4,4′diamine; tris-8hydroxyquinolinolate) or inorganic of covalent structure such as of silicon or ionic structure such as semiconductor oxides processed by technologies involving different, reactive and non-reactive deposition techniques such as physical deposition, chemical deposition and physical-chemical deposition of thin films at an atomic scale level, performed at temperatures close to room temperature, namely:
cathodic sputtering of direct current or radio frequency;
thermal resistive or electron gun deposition in vacuum;
assisted or non-assisted chemical decomposition of vapors by radio frequency plasma or ultra high frequency;
heating in vacuum;
epitaxial atomic growth;
deposition via ink-jet;
chemical emulsion.

The techniques listed allow the controlled growth of films with thicknesses between 1 nm and 50 μm of organic and inorganic materials, without damaging the paper or the electronic performance of the material deposited.

### SUMMARY

The present invention describes a process of manufacturing an active electronic or optoelectronic, field-effect semiconductor device that incorporates a thin film (2), based on natural, synthetic or mixed fibers, both as support and dielectric (2) of the referred device, turning it into self-sustainable.

In a preferred embodiment of the present invention the thin film (2) comprises cellulosic material or bio-organic paper.

Another preferred embodiment the present invention comprises one or more additional components, of organic or inorganic origin, with electrical characteristics of a metal (3, 5), semiconductor (1), insulator (6) or an adaptation layer (4), in single or discrete structures, composed of tandem or multilayer structures, in order to realize active devices, particularly, the diode junction or transistors, or particularly, devices of two, three, or four hybrid terminals.

Still another preferred embodiment the present invention applies to the referred cellulosic material or bio-organic paper, a passivation or adaptation or adaptation layer (4) prior to depositing any other component element of the final device.

Still in another preferred embodiment of this invention the referred passivation or adaptation layer (4) includes high electrical resistivity dielectric material, in particular with thicknesses up to 2000 nm.

Still another preferred embodiment of the present invention comprises the said components at temperatures close to room temperature and that these can be optionally annealed up to 150 degrees Celsius.

Also another preferred embodiment of the present invention comprises the deposition of components by one or more of the following methods: resistive thermal evaporation by electron gun in vacuum, cathodic sputtering of direct current or magnetron assisted or non-assisted radio frequency or ultra high frequency, radio frequency or ultra high frequency assisted or non-assisted chemical vapor decomposition, ink-jet printing, or chemical emulsion.

Another preferred embodiment of the present invention includes depositing thin films according to specific drawings directly printed by protective resin before or after the production process, by using masks or by direct writing on the material deposited on the paper.

Still another preferred embodiment of the present invention includes depositing conductive component or components (3, 5) comprising organic or inorganic materials, metallic or semiconductor oxide of high conductivity, with thicknesses up to 10 μm.

Still another preferred embodiment of the present invention includes depositing semiconductor component or components (1) comprising an inorganic covalent material or single or compound ionic material or organic material with thicknesses between 2 nm and 20 μm.

Still another preferred embodiment of the present invention includes encapsulating the final device by a dielectric (6) with a thickness up to 10 μm.

In another preferred embodiment of the present invention has the said cellulosic material or bio-organic paper (2) being obtained from natural, synthetic or mixed cellulosic fibers produced by regeneration, dissolution or mixed techniques with the capability to control the degree of permanent ionic electro-negativity.

The present invention further describes an active electronic or optoelectronic field-effect semiconductor device comprising a natural, synthetic or mixed thin film (2), both as support and dielectric (2) of the said device, turning it into self-sustainable.

Still in another preferred embodiment of the present invention the thin film (2) comprises cellulosic material or bio-organic paper.

Still another preferred embodiment of the present invention comprises one or more components, of organic or inorganic origin, with electrical characteristics of a metal (3, 5), semiconductor (1), insulator (6) or of adaptation (4), in single structures, tandem compound structures or multilayer structures, in order to achieve active devices, particularly, the diode junction or transistors, or particularly, devices of two, three, or four hybrid terminals.

Still in another preferred embodiment of the present invention comprises a passivation or adaptation layer (4) immediately on the said cellulosic material or bio-organic paper.

Still in another preferred embodiment the passivation or adaptation layer (4) comprises dielectric material of high electrical resistivity, in particular with thicknesses up to 20,000 nm.

Also in another preferred embodiment of the present invention the conductive component or components (3, 5) comprise organic or inorganic material, or metallic or semiconductor oxide of high conductivity, with thicknesses up to 10 μm.

Still in another preferred embodiment of the present invention the semiconductor component or components (1) comprise inorganic covalent material or simple or compound ionic materials or organic materials with thicknesses between 2 nm and 20 μm.

Still in another preferred embodiment of the present invention the final device is encapsulated by a dielectric (6) with a thickness of up to 10 μm.

Still in another preferred embodiment of the present invention the component parts of the paper acting as dielectric (2); the region of the discrete channel deposited on the fibers consisting of organic or inorganic active semiconductors, either covalent or ionic; the drain and source regions (5) and the gate region (3) which are constituted of conductive oxides or metals of continuous structure or based on interconnected conductive islands. Still another preferred embodiment of the present invention is made up of structures such as metallic electrode (3)-paper (2)-semiconductor (1), wherein the paper (2) of cellulose or bio-organic origin acts as a dielectric wherein its electrical charge capacity per unit area is dependent on how the fibers are distributed and interrelated in the various mechanically compressed plans forming the paper, the transparent metal or not to be used as the material deposited to constitute the drain, source (5) and gate (3) regions and the semiconductor being the channel region (1) constituent.

Still in another preferred embodiment of the present invention the device is a p or n type field-effect transistors, able to switch from OFF to ON state or to amplify electrical and electronic signals, highly dependent on the electrical charge capacity per unit area associated with the paper and preferably to the method used of associating and distributing its fibers.

Still another preferred embodiment of the present invention comprises two materials, deposited on the semiconductor layer of the device, the materials presenting a perfectly equal high conductivity in terms of conductivity and being separated from each other at distances that range from 1 nm to 1000 μm, respectively designated drain region and source region (5) and which allow the effective integration of the dielectric of the paper through its constituents.

Still in another preferred embodiment of the present invention the drain and source regions (5) are constituted by an organic or inorganic covalent or ionic semiconductor with conductivities of at least three orders of magnitude higher to that of the semiconductor material deposited on the paper and onto which these semiconductors were deposited, hereinafter designated channel region (1) with thicknesses ranging from 2 nm to 20 μm, of the same order of magnitude or inferior to the thickness of the fibers forming the paper (2), allowing the production of continuous or semi-continuous deposits in the surrounding regions of the channel region and which are used as drain and source (5) of p or n type field-effect transistors.

Still in another preferred embodiment of the present invention the channel region (1) consists of an organic or inorganic ionic or covalent p type or n type semiconductors in discrete or continuous form with thicknesses that range 2 nm and 20 μm, being of the same order of magnitude or less to the thickness of the fibers forming organic paper (2) with conductivities of at least three orders of magnitude lower than that of materials used for form the drain and source regions (5).

Still in another preferred embodiment of the present invention the p or n type transistors are connected without the application of any signal or application of a gate voltage in order to be connected to the ON state, either for the switching mode or the amplification of electronic signals mode, which is a function of the charges accumulated per unit area in the fibers forming the paper.

Still in another preferred embodiment of the present invention the active semiconductor used on the paper is replaced by two semiconductors (1, 7) of complementary electronic nature, p and n type, or vice-versa, juxtaposed and separated at distances between 100 nm and 1000 μm.

Still in another preferred embodiment of the present invention the two semiconductors to be deposited on the paper are connected by the same material that is respectively used as drain and source (5) of each one, acting as a common electrode.

Still in another preferred embodiment of the present invention the said cellulosic material or bio-organic paper (2) comprises natural, synthetic or mixed cellulosic fibers produced by regeneration, dissolution or mixed techniques with the capability to control the degree of permanent ionic electro-negativity.

### GROUNDING OF THE INVENTION

In terms of applications, the use of paper with interstrate functions for the creation of transistors is not known beyond its applications as support or passive dielectric in capacitors.

The present invention is of interest for the redefinition of the usage concept of paper in addition to its static functions or simple substrate for other active and dynamic functions providing the paper with simultaneous functions as electronic component and support thus allowing an auto-support for its integrated devices and systems rehabilitating the paper as a high-tech solution.

This development allows obtaining materials and creating flexible electronic self-sustainable and cost-effective disposable devices and allows manufacturing integrated circuits also self-sustainable giving another application to the paper in addition to drawing/writing in static form. In order to achieve these aspects, it is fundamental to conceive, manufacture, and create with paper, the same type of circuits that nowadays take place in other substrates and wherein the functionality in a whole or in part of the active devices is dependent on the usage of the paper as dielectric material (2) thus enabling the integration of both sides of the paper in a single monolithic or hybrid integrated circuit.

In order to achieve these aspects, it is necessary to combine dispersed and well-known technologies and adapt them to 3 levels of requirements: Manufacturing procedure; material and device Functionality; Integration.

In manufacturing and creation processes of electronic devices, the surface of the paper is prepared in a controlled atmosphere for the deposition processes. Unlike the conventional deposition processes, it is ensured that the entire deposition process takes place near room temperature, that there is no overheating derived from the deposition process in itself, and also that the materials deposited fulfill adhesion parameters, mechanical elasticity, chemical stability, and electronic and optics quality.

In order to obtain the above-mentioned features, the materials to be deposited on the sides of the paper used as support and dielectric are organic or inorganic metallic materials, semiconductor materials, other complementary dielectric and passivation materials (4,6).

The metals to be used and processed by one of the aforementioned technologies (3) such as silver, aluminum, copper, titanium, gold, chromium, and platinum, or any metal alloy resulting from the aforementioned elements or their multilayer deposition to be used in the manufacture of metal contacts (3, 5) and on rectifying junctions of the metal-insulator-semiconductor type, wherein the insulation is the paper itself or self-sustainable thin film with similar functions to those of the paper. In addition, the deposition process is also included for any thin inorganic film (degenerated semiconductor oxides such as tin oxide, zinc oxide and indium oxide, indium doped with tin, zinc oxide doped with gallium, zinc oxide doped with aluminum generally designated conductive and transparent oxides with resistivity inferior to 10⁻³ Ωcm) or organic with conductive characteristics of a metal.

The active n or p type semiconductors (1) to be used may be organic or inorganic covalent semiconductors or active ionic semiconductors that correspond to the so called processing component of active field-effect devices designated channel region, wherein the dielectric is the paper (2) that also acts as physical support of the device.

In terms of organic semiconductor materials the following should be highlighted: tetracene, pentacene, copper phthalocyanine, titanium oxide phthalocyanine, and zinc phthalocyanine, among others, with conductivities ranging from 10⁻¹³ Ω⁻¹cm⁻¹ e 10⁵ Ω⁻¹cm⁻¹.

In the case of covalent inorganic semiconductors to be used, these may be the silicon in its amorphous, nanocrystalline or micro/polycrystalline forms, doped/non-doped with phosphorus, arsenic or boron with conductivities ranging between 10⁻¹⁴ Ω⁻¹cm⁻¹ and 10³ Ω⁻¹cm⁻¹.

In terms of ionic inorganic semiconductors to be used, these will focus mainly on simple or single semiconductor oxides, nanocomposites or multi-compounds, such as zinc oxide, tin oxide, indium oxide, titanium oxide, copper oxide, aluminum oxide, copper aluminum oxide, nickel oxide, titanium oxide, copper oxide, aluminum oxide, aluminum and copper oxide, nickel oxide, ruthenium oxide, cadmium oxide, tantalum oxide, indium and zinc multicompound oxides, indium and zinc, gallium multicompound oxides, zinc and tin, copper and aluminum multicompound oxides, silver and copper multicompound oxides, titanium multicompound oxides, copper, zinc, tin and silver, whatever the percentages of compositions may be, with conductivities ranging from 0⁻¹⁴ Ω⁻¹cm⁻¹ to 10⁴ Ω⁻¹cm⁻¹.

In terms of materials of high resistivity used as passivation or adaptation materials or as second dielectric in the growth of interfaces (4), these shall be based on oxides, nitride compounds with thicknesses between 2 nm and 10000 nm such as silicon dioxide or silicon nitride, or organic material or any other single or multilayered material, such as tantalum oxide, hafnia, zirconia, yttrium oxide, alumina or compounds such as hafnia/tantalum oxide, alumina/tantalum, hafnia/alumina; silicon dioxide/tantalum pentoxide, tantalum/yttrium; zirconia/tantalum, tantalum pentoxide/silicon dioxide, alumina/titanium oxide or PMMA, or POMA, or mylar, all being processed at temperatures ranging from −20 degrees Celsius to 150 degrees Celsius, aiming not only to be highly compacted and with extremely flat surfaces, but also that the structures of the materials are amorphous or nano-structured in order to besides introducing the required difference in work functions with the material forming the channel, to achieve the desired electrical insulation, wherein the spatial geometry definition of the device constituent is done by using a normal standard lithography technique, or by mask or lift-off. In this case, for example, the deposition of the positive resin on the dielectric, wherein the resin is going to protect the areas of the material that are not intended to be removed and the rest are removed by a dry or wet selective erosion process which in fact removes the unprotected dielectric material.

In addition to these materials that can make direct contact with the paper, there are other materials to be processed upon the already-mentioned materials in order to constitute an active device such as the materials that constitute the drain and source regions (5) in the field-effect transistors and that can be highly doped materials when the channel region is a covalent semiconductor or metals or metal alloys that act simultaneously with contacts of thicknesses up to 10 μm, in the case where the active semiconductor is an ionic semiconductor or an organic semiconductor.

In terms of devices, it is intended to:
Create and manufacture diodes of metal-insulator-semiconductor (MIS) structure in which the insulator is a sheet of paper containing metal on one of the sides and the active semiconductor deposited on the other side using any of the previously mentioned technologies ((1), (2), (3));
Create and manufacture n and p field-effect transistors based on thin films (FIGS. 3 to 5) in which the dielectric is the paper, consisted of natural or synthetic or mixed cellulosic fibers, lumped in multi layers by a resin and glue whose electronegativity and ionicity are controlled, being then mechanically compressed, the active semiconductor forming the channel region is an inorganic ionic semiconductor or inorganic covalent semiconductor or organic semiconductor (1) and the drain and source regions are respectively based on a highly conductive oxide or on a metal or on a covalent semiconductor highly doped n type or p type p, with the capability to act as a switching key and also act as information conductors/receivers and amplifiers. These devices have a constitution as shown in FIGS. 3 to 5, in which the channel (1) may have lengths ranging between 1 nm and 1000 μm being directly deposited on the paper or on an interface adaptation layer previously deposited on paper (4) along with the films that makes the source and drain regions (5) and on the other side of the paper (2) the gate electrode (3) is deposited directly or through an adaptation layer consisted of a metal or a highly conductive oxide. These devices have mobility exceeding 0.5 cm²V⁻¹s⁻¹, closed state/open state ratios exceeding 10⁴ and operating in enhancement mode or depletion mode, that is, energy is required for them to be turned on or else, they are already in the on state without the application of any energy;
Create and manufacture field-effect transistors processed in the above-mentioned conditions, but in which the active semiconductor or the materials forming the gate electrode or drain and source regions are organic materials such as tetracene, pentacene, copper phthalocyanine, titanium oxide phthalocyanine, zinc phthalocyanine, among others.
Create and manufacture CMOS or C-MESFET devices wherein the dielectric material is the paper and the complementary n and the p type semiconductors incorporated in the device are inorganic covalent semiconductors, or inorganic ionic semiconductors or organic semiconductors, or any of its possible hybrid combinations as shown in FIG. 6. That is, a device based on two p and n type transistors, with a common gate wherein one of the output terminals (source and drain or vice versa) is common and the other two output terminals are independent.

An aspect of the present invention is to provide a new application for cellulosic-based or bio-organic-based paper, in which it ceases to be a merely static mean of support in order to become a component in the self-sustainable conception of the production and creation of electronic and optoelectronic components and systems, which are designated interstrate.

There is no state of the art patent that is known in terms of the cellulosic-based or bio-organic-based paper technique with the functionalities mentioned earlier. That is, of C-MOS interstrate structure characterized in that it allows producing and creating flexible self-sustainable disposable and integrated devices of monolithic or hybrid type and simultaneously characterized in that it is a device or system components that is developed on its own two sides.

The research made in several patent records databases showed that none of the processes, products and systems functionality of the paper which is subjects in the present invention were published or submitted for patent.

The concept behind the present invention is new and, although its embodiments are sustained by known technologies, its novelty lies within the scope of a new set of purposes.

### BACKGROUND OF THE INVENTION

The state of the art of the present invention, as well as patent documents prior to the present invention, that might be related thereto, will be hereinafter described.

In terms of industry, design or application, any activity related or corresponding to the subject of the present invention is unknown, in its aspects of integrated process, products and systems.

The research undertaken resulted in the following patents and prior art references, although not considering the use of a cellulose support.

1. The national patent application No. 103951 issued in 2008 refers to the use of cellulosic based or cellulosic bio-organic paper as a physical support for the processing of electronic devices and systems and not to its integration in the processing and support of the electronic devices and systems. Therefore, in national patent 103951, paper is a simple physical support of electronic devices that are produced by any conventional technology using covalent semiconductor or organic and inorganic ionic semiconductors, including the respective metal connections. The only similar point between this patent and the one previously mentioned is that the processing technologies of materials forming the devices are the same. In national patent 103951, the devices do not integrate paper in its functionality in the function designed interstrate which is unique and corresponds to an innovation that leads to the creation of completely new transistorized devices and with also innovative operating principles when compared to conventional devices. This patent explores the potential associated with the fibers forming the paper which lead to the concept of discrete dielectric as opposed to what is known in conventional field-effect devices based on continuous dielectric films, which promotes an increase of several orders of magnitude of the capacity per unit area of the paper, without changing the relative low value, between 1.5 and 12, of the relative dielectric constant. In order for this to happen, the production of active semiconductors should have thicknesses of at least one to two orders of magnitude lower than the thickness of the fibers that constitute the paper. This condition causes the thickness of the active semiconductor used to be always less than 100 nm. This condition is not observed in the National Patent 103951 wherein it is intended to obtain a surface as smooth and uniform as possible since the paper simply acts as a physical support wherein single devices or integrated electronics are deposited.
2. U.S. Pat. No. 3,617,372 filed in 1967, refers to electroconductive paper for producing electrostatic images, wherein action takes place in the manufacture region of paper in volume, allowing it to contain polymer chains from hydroxyethyl and hydroxypropyl group in order to adequate paper to image capture functions, and provide non contact printing. The patent is not in force. It was related to the paper in volume constituent in image capture and image recording, not being related whatsoever to its use as an electronic component.
3. Japanese Patent JP2003123559, “Forming method and its device for transparent conductive film, transparent conductive film and electronic paper”—aims the production of transparent and conductive films at low temperatures, named Indium Tin Oxide, ITO (or ZnO), via CVD assisted by a plasma using gaseous forms of indium iodide and tin chloride (zinc nitrate (Zn(NO₃)2.6H₂O)) in an oxygen atmosphere, with or without an inert gas such as Argon, deposited on polythiophene polymer membranes or other organic-based material, in order to use in the so-called electronic paper (e-paper). That is, the possibility to rewrite alphanumeric characters or images on a flexible film based on a transparent conductive oxide deposited on an organic substrate. In this case, for example, the transparent conductive oxide is intended to serve as an electrode for the application of electrical fields to control image hue, for example those formed from the orientation of liquid crystals. This patent is about a process for obtaining films, system thereof, and physical-mechanical characteristics of the films thus obtained, such as adhesion. That is, an aspect of the invention is to provide the production of organic substrates of conductive oxides to be simply used as electrodes, not comprising in the patent the use of cellulose-based paper or bio-organic paper, simultaneously, as an electronic component and as the support of the device that it incorporates.
4. U.S. patent U.S.2006/0132894—discloses the deposition of transparent conductive oxides on both faces of the electronic paper having as main target applications similar to those described in JP2003123559. In other words, it is directed to adaptation technologies used in displays namely liquid crystal for new flexible displays produced on organic media. Thus, the claims of this patent are included in the scope of equipments used and of how to process and retain an image on organic flexible substrates, comprising the control of non conductive particles placed within the paper itself or under the oxides produced, with the capability to change their degree of transmittance by applying an electrical field. This is not within the scope of the present invention.
5. Canadian patent CA682814 “Electrically conductive paper, and method of making it”—relates to the volume processing of conductive paper, in particular to the inclusion of conductive fibers in its volume coated or not by metal, randomly dispersed in a cellulose matrix. This is not within the scope of the present disclosure, which does not include manipulating the paper structure.
6. The Canadian patent CA767053 “Electrically conductive paper”—refers to coating of cellulosic paper in conductive volume, coated with an insulation photoconductor material, associated with the incorporation of zeolites, able to ensure a resistivity inferior to 10¹² Ωcm, aiming for the development and maintenance of electrostatic charges for information printing. This is not within the scope of the present disclosure wherein the paper is intended to function as a dielectric in active devices and simultaneously, as the support of the different components forming the device meant to be developed on both faces of the paper.
7. Canadian patent CA898082 “Polymeric quaternary derivatives of 4-vinyl pyridine in electrically conductive paper” refers to the use the quaternary polymers capable of receiving photoconductor coatings capable of producing electrostatic copying paper. This is not the scope of the present invention.
8. Canadian patent CA922140 “Electro-conductive paper”-deals with the electro-conductive paper with polymers with at least 75% of its constitution useful in the techniques for image reproduction. The patent protects all compositions containing radical structures of the type:

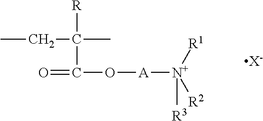

This is not the scope of the present invention.

From de above-description, one might conclude that in terms of the product and method disclosed in the present invention, no publication or patent application related thereto.

The patents and references mentioned correspond to the state of the art wherein the present disclosure might be found, there being some peripheral points in common, in terms of process and materials used as conductors, on plasticized surfaces and the processes take place in some cases at room temperature. However, the existence of work and patents or patent applications that focus on using cellulose-based paper simultaneously as a component in active devices with memory effect and physical core of these devices, their derivatives or compounds are unknown.

The present invention consists in the creation of a new electronic device wherein the paper is an active component acting as support, which we call interstrate, and which is manufactured using different technologies, seeking to obtain products and electronic systems that incorporate natural, synthetic or mixed cellulosic or bio-organic-based paper, or mixed compounds derivatives thereof which determine the final functionality of these products and systems. It is unknown, in laboratory or performed attempted, the manufacture of such devices. These are the central aspects of the present invention, which results in a hybrid quality but still monolithic in terms of the integration of electronic components that produce new effects and add a new value in the application of the invention, which is not present in the state of the art systems.

### BRIEF DESCRIPTION OF THE DRAWINGS

FIG. 1 is a schematic view of the basic structure of a non-encapsulated diode constituted by Metal, Insulator and Semiconductor called MIS diode in which electrical contacts are made of materials or metallic alloys according to the following reference:

1—n or p-type active organic semiconductor or covalent inorganic or ionic inorganic semiconductor;

2—paper of cellulose or bio-organic origin used simultaneously as dielectric and physical support (substrate) of the electronic components;

3—gate electrode that is used to establish the electrical contact with the device constituted by a metal or a metal alloy or due to the successive deposition in the multilayer form of two metals or an oxide semiconductor of very high conductivity or by an organic material of very high conductivity.

FIG. 2 is a schematic view of the basic structure of a non-encapsulated diode constituted by Metal, Insulator and Semiconductor called MIS diode in which the electrical metal contacts are made by conductive oxide of high conductivity and in which an adaptation layer is in one or both sides of the sheet of paper before the deposit of materials that constitute the metallic or semiconductor component according to the following reference:

4—Passivation or adaptation layer of interfaces to exist in one or both paper interfaces.

FIG. 3 is a schematic view of a n or p type field-effect transistor in which there are two adaptation layers between the materials deposited and both surfaces of the paper used as dielectric and in which the source and drain regions are deposited on the active semiconductor according to the following reference:

1. Active n or p type semiconductor acting as the channel region in the field-effect transistor;

2. Paper acting as dielectric of the field-effect transistor.

3. Gate electrode (metal or highly conductive oxide or organic highly conductive semiconductor).

4. Dielectric channel adaptation layer (4) and/or dielectric gate electrode

5. Source and drain regions of the field-effect transistor consisting of a highly doped semiconductor or organic semiconductor of high conductivity such as the P-dot when the channel region is based on a covalent semiconductor or by a metal or P-dot or singular semiconductor oxide, a compound or multi-compound of high conductivity when the channel region is an ionic oxide or an organic semiconductor.

6. Encapsulation layer, surface passivation.

FIG. 4 is a schematic view of a non-encapsulated n or p type field-effect transistor wherein an adaptation layer is placed between the deposited materials on the side of the paper surface used as dielectric which contains the active semiconductor that overlaps the source and drain regions according to the reference.

FIG. 5 is a schematic view of a non-encapsulated n or p type field-effect transistor wherein an adaptation layer is placed between the deposited materials on the side of the paper surface used as dielectric that contains an active semiconductor that overlaps the source and drain regions according to the references.

FIG. 6 is a schematic view of a non-encapsulated n or p type field-effect transistor wherein there is no adaptation layer placed between the deposited materials and the two paper surface used as dielectric and wherein the active semiconductor overlaps the source and drain regions acting as enhancement or depletion method according to the references.

FIG. 7 is a schematic view of a non-encapsulated CMOS field-effect device in which there is no adaptation layer between the deposited material and the two surfaces of the paper used as dielectric and wherein the active n or p semiconductors or vice versa overlap the drain and source regions according to the references:

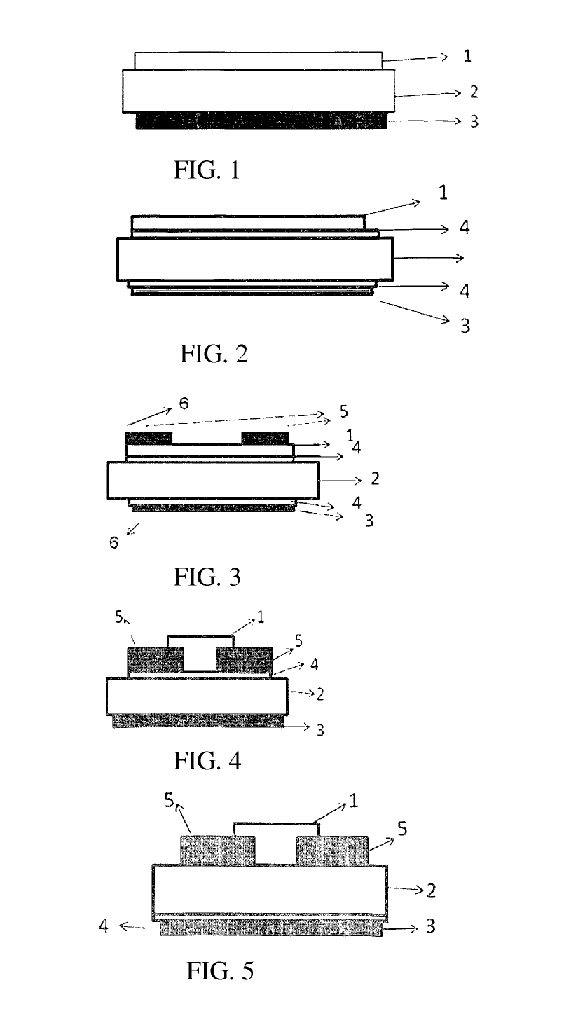

7—Channel region whose semiconductor type is complementary to the channel of the semiconductor corresponding to reference in FIG. 1 wherein if it is n type, then the supplement will be p type or vice versa.

FIG. 8 is a schematic view of a non-encapsulated CMOS field-effect device wherein two adaptation layers are placed between the deposited material and the two surfaces of the paper used as dielectric and in which the active n or p type semiconductors or vice versa, being separated from each other by distances between 100 nm and 1000 μm and which overlap the drain and source regions according to the references.

### DETAILED DESCRIPTION OF THE PREFERRED IMPLEMENTATION OF THE INVENTION

The present invention refers to the use of cellulose-based paper or cellulosic compounds of different weighs and compositions or of bio-organic origin acting simultaneously as dielectric and physical support leading to the creation of singular or integrated electronic and optoelectronic devices and adequacy of deposition processes compatible with the manufacture of these new devices that must be selected and controlled so as not to damage the interstrate paper. To this end, all the manufacturing processes are carried out at temperatures below 150 degrees Celsius, especially those occurring on the surface of the paper.

The present invention is capable of different configurations depending on the desired specific application. The present invention allows using paper simultaneously as substrate and dielectric in different types of electronic circuits that lead to the creation of new electronic devices with distinct functionality from that of conventional electronic devices, namely field-effective electronic devices.

Therefore, The present invention corresponds to the creation of a new device presenting a set of innovative features of new electronic devices that by using new innovative processes, enable new products and systems that involve paper in its double function of physical support and component of active devices or integrated circuits based on them with exceptionally high capability per unit area of the dielectric paper and due to the fibers forming the paper.

### A. Diode Junction Processing

FIGS. 1 and 2 are an illustration of a diode of the Metal Insulator Semiconductor type designated MIS structure. In FIG. 1 there is no adaptation layer of the material interfaces to be deposited on the two surfaces of the paper whereas the second example illustrates such a case, besides the metallic electrode is based on a degenerated semiconductor oxide. In all cases, the active semiconductor may be an organic or inorganic covalent or ionic known semiconductor. Any of the components forming the device can be manufactured by well-known physical, chemical or physical-chemical deposition techniques, such as the ones discriminated below.

The operating principle of the device is based on the so called field-effect wherein the collected charges in the semiconductor are functions of the electric field applied to the metal electrode designated the gate electrode and the current flowing in the semiconductor is a function of the capacity per unit area of the paper which is a result of how the fibers are distributed and joined.

### B. MIS Junction Manufacturing Process

In a first step, regardless of the type and weight of the paper used, it is necessary to prepare and to condition the surface, taking its texture into account and the intention to manufacture continuous films. This is achieved by:
a) Either by subjecting both surfaces of the paper to UV treatment for 10 minutes;
b) Or by subjecting both surfaces of the paper to vacuum treatment consisting of submitting the surface, before deposition, to a dc or RF discharge in an Argon, Nitrogen or Xenon atmosphere, at pressures between 1-10⁻² Pa, for 5 minutes using power densities between 0.1-3 Wcm⁻²;
c) Or by depositing a passivation film—which may be made of ceramics, oxidized or nitride or fluoride—with a thickness ranging from 2-200 nm;
d) Or by cleaning the surface with a nitrogen/hydrogen jet flow, in order to remove free nano-particles and activate the surface (being the function of the hydrogen in the nitrogen mixture).

Once the surface is prepared, the same is transferred to the environment wherein the various production steps will take place, according to the action intended:
i) For the processing of the metallic electrode, represented in FIGS. 1 and 2 with reference 3 consisting of a deposit of an inorganic metallic or conductive oxide material or organic material such as the P-dot produced by any of the following techniques:
   I) Thermal resistive or electron gun evaporation process in vacuum using vacuum pressures below 10⁻³ Pa and systems in which the substrate temperature is controlled by cooling. The minimum thickness to use is of 10 nm. This process can be implemented and carried out in a continuous form (roll to roll).
   II) magnetron-assisted cathodic sputtering (DC or RF) in argon atmosphere, with controlled temperature of the substrate (cooling), with vacuum pressures between 1 Pa and 10⁻¹ Pa and wherein the substrate target distances may vary between 5 cm and 15 cm depending on the dimensions of the target and of the sheet of paper to be deposited.
   III) ink-jet printing from a chemical solution containing organic or inorganic components, wherein the minimum thickness of the deposited material is of 10 nm.
   IV) The rapid spread of chemical emulsion of a chemical solution containing the elements to be deposited with thicknesses up to 400 nm.
ii) For the processing of the organic or inorganic ionic or covalent active semiconductor referenced by number 1 in FIGS. 1 and 2 one of the following techniques is used:
   V) magnetron-assisted cathodic sputtering (DC or RF) using a reactive atmosphere and metallic targets or reactive or non-reactive atmospheres and ceramic targets, with different compositions and purity grades. The vacuum pressures to be used may vary between 1 Pa and 10⁻¹ Pa and the partial pressure of oxygen may vary between 10⁻⁴ Pa and 10⁻² Pa; wherein the target substrate distances vary between 5 cm and 15 cm, depending on the dimensions of the target to be used and on the dimensions of the sheet of paper to be deposited. The thickness to be used is of 10-5000 nm.
   VI) Thermal evaporation in vacuum, by resistive or by electron gun methods, from ceramic/oxide materials containing the metallic elements to be deposited and whose process is conducted at vacuum pressures below 10⁻³ Pa, following the procedures previously described for this technique. The thickness to be used is in the order of 10-20000 nm.
   VII) Radio frequency plasma- or UHF-assisted chemical vapor decomposition. In this case, the elements to be deposited are in the gaseous form. For example, in the case of silicon deposition, it is in the form of silane and is decomposed by an RF discharge at a pressure ranging 10-200 Pa, using power densities between 0.03-2 Wcm⁻² and excitation frequencies between 13.56 MHz and 60 MHz. The useful thickness of the active semiconductor ranges from 20-8000 nm.
   VIII) The ink-jet printing from a chemical solution containing organic or inorganic components, wherein the minimum thickness of the material deposited is of 20-5000 nm.
   IX) Rapid spread of a chemical solution containing elements to be deposited wherein the thickness of the deposited material will be of 20-20000 nm.
iii) For the processing of the adaptation layer referred to in FIGS. 1 and 2 with reference number 4 or the encapsulation layer referred to in FIGS. 1 and 2 with reference number 6 the manufacturing process to be used is indicated in item ii), using the same type of materials but now with at least 3 orders of magnitude more electrically resistive than the electrical resistivity shown by the active semiconductor, whatever it may be.

### C. Processing of Field-Effect Transistors

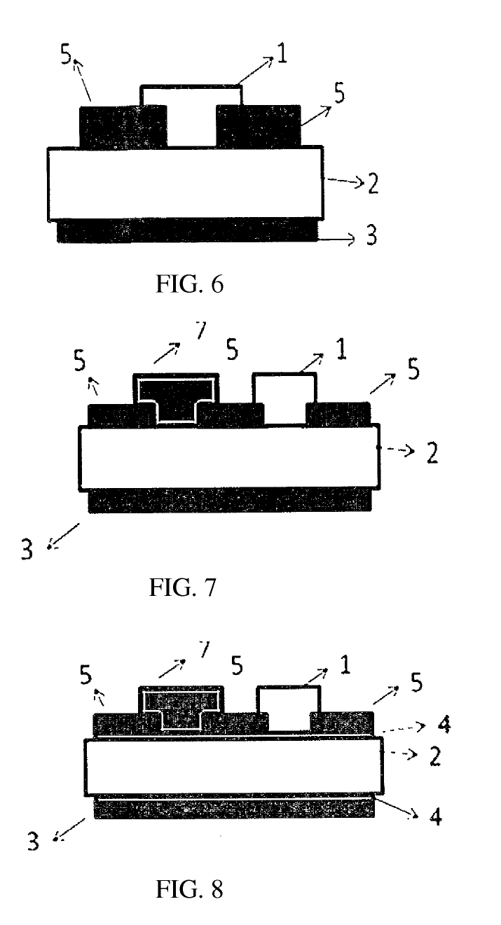

This section describes the processing of encapsulated or non-encapsulated n or p type field-effect transistors with or without adaptation layer at the interfaces as shown in FIGS. 3 to 6 working in the enhancement or depletion mode, i.e., may or may not have the need to apply a voltage to the gate electrode in order to be in the ON state or on the amplification state. This function is the key to switch to the information address or amplified circuit and also acting as the signal conductive circuit in which the current circulating in the semiconductor depends on the electrical and ionic charge capacity per unit area of the interstrate paper which depends on how the fibers are distributed. FIGS. 3 to 6 are schematic views of field-effect transistors with different types of interface passivation or adaptation.

The materials to be used as active covalent p type or n type semiconductor for the processing of the channel region, referenced by number 1 in FIGS. 3 to 6, are mainly based on doped or non-doped silicon or ionic oxides such as zinc oxide, zinc oxide alloying to aluminum, tin oxide alloyed to fluoride, or copper oxide, or cadmium oxide or silver oxide, or silver oxide, or compound alloys of indium and molybdenum, or compound alloys of indium and tin, or compound alloys of indium and zinc, or compound alloys of zinc and gallium, compound alloys of zinc and gallium and indium, compound alloys of zinc and silver and indium, or compound alloys of indium and zinc and zirconium, or compound alloys of indium zinc and copper, or compound alloys of indium and zinc and cadmium, or compound alloys of indium and zinc and tin, compound alloys of gallium and tin and zinc, or compound alloys of indium and zinc and molybdenum, or compound alloys of hafnia or titanium or alumina or tantalum or oxide in compositions that vary from 0.1% to 99.9% of its constituents, showing resistivity between 10¹¹-10⁰ Ωcm, function of the composition and the partial pressure of oxygen used during the manufacturing processes. The technology processes to be used are the ones described in A ii). The useful thickness of the drain and source regions range from 2-20000 nm.

For the processing of the drain regions, referenced by number in FIGS. 3 to 6, the same semiconductors referred to earlier need to be used but with lower resistivity, between 10⁰-10⁻⁶ Ωcm, using the same technologies previously mentioned. The useful thickness of the channel regions varies between of 2-20000 nm.

The encapsulation, adaptation and passivation layers to be use are the same as those mentioned in A.

### D—CMOS Device Processing

The example herein described consists of the use of two field-effect transistors, one of n type operating in enhancement mode, as shown in FIGS. 7 and 8 by reference number 1, and the other of the p type operating as dynamic charge, indicated by reference number 7, produced according to previously described techniques, wherein the separation of the active regions of the two transistors may vary between 100 nm and 100 μm, with or without the passivation layer of both or one of the surfaces of the sheet paper composed by fibers that determine its capacity and that correspond to the manufacture of a device designated C-MOS. In this type of circuit, the two transistors are never simultaneously in the ON state, allowing its use in the conception of digital circuits and in the conception of logical gates.

It should be clear that the achievements of these devices and semiconductor circuits and their previously described applications are merely possible implementation examples, mainly established for a better understanding of the principles of the invention. Variations and modifications can be made to the above achievements without substantially departing from the spirit and principle of the invention. All these modifications and variations must be included within the scope of the present disclosure and invention and be protected by the claims of the invention.

### Implementations

The main industries that currently may come to use the devices and integrated circuits resulting from the use of present innovation are the electronics industry, the semiconductor industry, the flat screen industry, the logical circuit industry, the instrumentation and sensor industry, the medical and biotechnology industry, the optoelectronics industry, and the micro and nano-electronics industry. The devices based on the present invention are meant for direct application in all electronics based on field-effect devices, to act as switches or amplifiers, which may include circuits for information orientation (drivers), the addressing matrices for flat screens, conception of logical circuits, namely inverter logical gates, e or (AND or OR) type logical gates, and complementary forms thereof (NAND and NOR), ring oscillators, manufacture of hetero-junctions, namely MIS diodes and CMOS devices; in instrumentation industry; in the medical and/or food industry, as the key element to switch control circuits and signaling circuits; defense industry, to the design of stealth, invisible displays among others.

The present invention aims to develop a product or products using simple and inexpensive processing techniques, using paper simultaneously as physical and dielectric support of the devices and integrated systems meant to be manufactured which implies the utilization of processing techniques that stay in line with the processing of thin films on both sides of the cellulose or bio-organic paper at low temperatures.

On the other hand, the required manufacture technologic processes are compatible with those already existing in the electronics industry, or in the optoelectronics industry, or in semiconductor industry, namely the cathodic sputtering processes for large areas, or thermal evaporation or sol-gel or ink-jet processes, hence no requiring high investments in terms of research and matching technology.

The technical advantages offered by the present invention allow the active use of the paper in a dynamic way and not only in a static way, acting as a substrate and component of the electronic devices that are produced from it.

Although the preferable implementations offered by the present invention have been described in detail, it should be understood that many variations, substitutions and changes may be made without departing from the scope of the present invention, even though all the advantages identified above are not present. The achievements herein presented illustrate the present invention which can be implemented and incorporated into a variety of different ways, which fall under the scope of the invention. Also, the techniques, constructions, elements, and processes described and illustrated in the possible implementation as distinct or separate, may be combined or integrated with others techniques, constructions, elements, or processes, without deviating from the scope of the present invention. Although the present invention has been described in several embodiments, these can still be modified according to the scope of implementation of the present invention. Other examples of variations, substitutions, and alterations are easily identified by those skilled in the art and could be introduced without departing from the spirit and scope of the present invention.

1-30. (canceled)

31. A manufacturing process of field-effect electronic or optoelectronic devices comprising incorporating natural, synthetic or mixed fibers bonded in layers bonded into a thin film both as physical support and dielectric of said device, thus allowing the device to be self-sustainable.

32. The process according to claim 31, wherein the fibers, the layers, or the fibers and the layers are bonded by an adhesive, said adhesive being a modifier of electronegativity and ionicity.

33. The process according to claim 31, further comprising the deposition of active semiconductors 10 to 100 times thinner than the thickness of said fibers.

34. The process according to claim 31, wherein said fiber layers are mechanically compressed obtaining a electrical and ionic charge capacity per unit area, dependent on how the fibers are distributed, interrelated and joined in the various mechanically compressed plans.

35. The process according to claim 31, further comprising the deposition of active semiconductors 10 to 100 times thinner than the thickness of said fibers; wherein the fibers, the layers, or the fibers and the layers are bonded by an adhesive, said adhesive being a modifier of electronegativity and iconicity; wherein said fiber layers are mechanically compressed obtaining a electrical and ionic charge capacity per unit area, dependent on how the fibers are distributed, interrelated and joined in the various mechanically compressed plans.

36. The process according to claim 31 further comprising incorporating one or several additional components either organic or inorganic with electrical characteristics of a metal, a semiconductor, an insulator or an adaptation layer in single structures, composed tandem structures or multilayer structures in order to carry out active devices, comprising diode junctions or transistors, or devices of two, three or four hybrids terminals.

37. The process according to claim 36 further comprising the deposition by any known conventional or non conventional chemical, physical or combination of both techniques such as sputtering, inkjet or chemical emulsion of said components at temperatures close to room temperature and in that these might be annealed up to 150 degrees Celsius.

38. The process according to claim 31 further comprising applying to said cellulosic material or bio-organic paper a passivation or adaptation layer prior to depositing any other component or part of the final device.

39. The process according to claim 31 further comprising the depositing of a semiconductor component which comprises a covalent inorganic material, a single ionic material, multicompound material or organic material, having a thickness between 2 nm and 20 μM.

40. The process according to claim 31, further comprising the deposition of active semiconductors 10 to 100 times thinner than the thickness of said fibers; wherein the fibers, the layers, or the fibers and the layers are bonded by an adhesive, said adhesive being a modifier of electronegativity and iconicity; wherein said fiber layers are mechanically compressed obtaining a electrical and ionic charge capacity per unit area, dependent on how the fibers are distributed, interrelated and joined in the various mechanically compressed plans.

41. An electronic or optoelectronic field-effect device comprising natural, synthetic or mixed fibers bonded in layers bonded into a thin film as a physical support and dielectric of said device, turning the device into self-sustainable.

42. The device according to claim 41, wherein the fibers, the layers, or the fibers and the layers are bonded by an adhesive, said adhesive being a modifier of electronegativity and ionicity.

43. The device according to claim 41, further comprising active semiconductors 10 to 100 times thinner than the thickness of said fibers.

44. The device according to claim 43 wherein said active semiconductor component comprises covalent inorganic material, single ionic material, multicompound ionic material, or organic materials, having at least a thickness between 2 nm and 20 μm.

45. The device according to claim 41, further comprising active semiconductors 10 to 100 times thinner than the thickness of said fibers; wherein the fibers, the layers, or the fibers and the layers are bonded by an adhesive, said adhesive being a modifier of electronegativity and ionicity.

46. The device according to claim 45 further comprising one or more components of organic or inorganic origin, having at least electrical characteristic of a metal as electrodes; a semiconductor, an insulator or adaption, in single structures, composed tandem structures or multilayer structures, so as to carry out active devices, comprising diodes, transistors, or devices of two, three or four hybrid terminals, or complementary metal oxide semiconductor, CMOS, devices.

47. The device according to claim 41 further comprising one or more components of organic or inorganic origin, having at least electrical characteristic of a metal as electrodes; a semiconductor, an insulator or adaption, in single structures, composed tandem structures or multilayer structures, so as to carry out active devices, comprising diodes, transistors, or devices of two, three or four hybrid terminals, or complementary metal oxide semiconductor, CMOS, devices.

48. The device according to claim 41 further comprising a passivation or adaptation layer immediately upon said cellulosic material or bio-organic paper.

49. P or N type transistor according to claim 41 comprising said device, which is:
on the ON state without requiring any application of an electrical signal voltage to the gate electrode,
either switching key mode or in amplification mode,
by changing the charge signal accumulated per unit area, in the fibers forming the paper.

50. Complementary pair device according to claim 49, wherein it comprises at least one pair of two such devices in complementary p and n type connection.
